(19) United States
(12) Patent Application Publication
(10) Pub. No.: US 2004/0262494 A1
(43) Pub. Date: Dec. 30, 2004

(54) Solid-state imaging device and manufacturing method thereof

(75) Inventors: Yuichi Egawa, Yokohama (JP); Akira Fukami, Hagashimurayama (JP)

Correspondence Address: Stanley P. Fisher, Reed Smith LLP, Suite 1400, 3110 Fairview Park Drive, Falls Church, VA, 22042-0681, US

(73) Assignee: Trecenti Technologies, Inc.

(21) Appl. No.: 10/873,110

(22) Filed: Jun. 23, 2004

(30) Foreign Application Priority Data
Jun. 27, 2003 (JP) P2003-183950

(51) Int. Cl. H01L 21/00; H01L 27/00; H04N 3/14

(52) U.S. Cl. 250/208.1; 348/302

(57) ABSTRACT

This invention provides a solid-state imaging device which enables its cell area to be reduced while maintaining a light receiving area. First, a plurality of isolation areas are formed in a semiconductor substrate. Then, p-type well is formed by implanting p-type impurity into the interior organization of an active area surrounded by the isolation areas. Next, by using ion implantation method, a charge accumulating area, which is a n-type semiconductor area, is formed deep in the p-type well. Consequently, photo diode is formed in a deep portion apart from the surface of the semiconductor substrate. After that, an electric transferring MIS transistor is formed above and apart from the charge accumulating area, so that the photo diode and the MIS transistor are formed in a vertical structure.

### CROSS-REFERENCE TO RELATED APPLICATION

The present application claims priority from Japanese Patent Application No. JP 2003-183950 filed on Jun. 27, 2003, the content of which is hereby incorporated by reference into this application.

### TECHNICAL FIELD OF THE INVENTION

The present invention relates to a solid-state imaging device and a manufacturing method thereof and more particularly to a technology effectively applicable to a solid-state imaging device capable of achieving a reduction in the cell size while maintaining its light receiving area and a manufacturing process for the same device.

### BACKGROUND OF THE INVENTION

There is a solid-state imaging device which takes an image by converting a light signal from an object into an electric signal and as this solid-state imaging device, for example, a charge coupled device (CCD) type image sensor, a CMOS type image sensor and the like are currently available.

In the CMOS type image sensor, for example, cells (pixels) are arranged two-dimensionally and individual cells can be selected by orthogonal scanning lines. When a cell is selected with the orthogonal scanning lines, an electric charge accumulated in the selected cell is outputted outside. By executing this operation (scanning) for all the cells arranged two-dimensionally, an electric signal corresponding to the object is outputted to an external device such as a display for displaying the image thereon.

The cell of this CMOS type image sensor includes a photo diode which converts received light to electric charges and accumulates and a transmission MOS transistor for outputting electric charges accumulated in the photo diode, and a transmission MOS is provided beside the photo diode (see, for example, Japanese Patent Application Laid-Open No. 11-126893 (page 7, FIG. 1), Japanese Patent Application Laid-Open No. 11-274450 (pages 3-4, FIG. 1), and Japanese Patent Application Laid-Open No. 2000-286405 (page 5, FIG. 2)).

Further, Japanese Patent Application Laid-Open No. 2002-016243 has disclosed a technology that the photo diode area is expanded to below an active area in which a transfer gate electrode is formed in order to improve its sensitivity.

However, the cell structure in which the transmission MOS transistor is formed sideway of the photo diode for receiving light has a problem that the cell area is enlarged.

According to the aforementioned Japanese Patent Application Laid-Open No. 2002-016243, a conductive area opposite to a well is formed on the surface of a semiconductor substrate just below the gate electrode. That is, a n-type low density impurity area is formed by implanting n impurity ion in the semiconductor substrate below the transfer gate electrode and a reset gate electrode. However, if the n-type MOS transistor channel area is formed in the n-type impurity area according to the above-described technology, a leak current increases when the gate voltage is 0 V. Consequently, a read-out charge decreases, which is a problem to be solved.

Further, according to the Japanese Patent Application Laid-Open No. 2002-016243, the photo diode has a structure of a n-type PDN area and p-type high density impurity area formed on the surface of the semiconductor substrate. That is, the p-type high density impurity area is formed above the n-type PDN area. However, if the p-type high density impurity area is formed on the entire surface of the n-type PDN area, when electric charges are transferred from the PDN area through the transfer MOS transistor, those electric charges pass through that narrow area because the n-type area in the vicinity of the surface is narrowed by provision of the p-type high density impurity area. Thus, there is a possibility that the transmission speed of electric charges may be lowered.

### SUMMARY OF THE INVENTION

Accordingly, an object of the present invention is to provide a solid-state imaging device capable of reducing the area of a cell while maintaining its light receiving area.

Another object of the present invention is to provide a manufacturing method for the solid-state imaging device capable of reducing the area of the cell while maintaining the light receiving area.

The aforementioned and other objects and novel features will be apparent from a description of this specification and accompanying drawings.

To achieve the above-described object, according to an aspect of the present invention, there is provided a solid-state imaging device having a plurality of cells for converting incident light to electric charge on a semiconductor substrate thereof, the cell comprising (a) a charge accumulating area for accumulating the electric charge; and (b) a field effect transistor for transferring the electric charge accumulated in the charge accumulating area out of the cell, wherein the charge accumulating area is a semiconductor area formed by implanting impurity of first conductive type into the interior organization of the semiconductor substrate such that it extends substantially in parallel to the surface of the semiconductor substrate while a part thereof extends to the surface of the semiconductor substrate and is exposed, and wherein, in the field effect transistor, a source area thereof is connected to the portion extended to the surface of the semiconductor substrate, of the charge accumulating area; a gate electrode is provided above an area of the charge accumulating area that is adjacent to the portion extending to the surface of the semiconductor substrate and that is exposed on the surface of the semiconductor substrate; and when the charge accumulating area is projected onto the device formation side of the semiconductor substrate, there existing an overlapping area between the charge accumulating area and the drain area of the field effect transistor.

Further, according to another aspect of the present invention, there is provided a manufacturing method of solid-state semiconductor substrate having a plurality of cells for converting incident light to electric charge in the semiconductor substrate, comprising the steps of: (a) forming a plurality of grooves in the semiconductor substrate; (b) forming a first insulating film on the surface of the semiconductor substrate containing the groove; (c) forming a first conductive film on the first insulating film formed such that the first conductive film fills the groove; (d) leaving the first conductive film within the groove and on a part of the active area in contact with the groove by patterning the first conductive film; (e) forming a gate electrode comprised of the first conductive film within the groove by polishing a side of the semiconductor substrate in which the groove is formed according to a chemical mechanical polishing method; (f) forming charge accumulating area in which the electric charge is accumulated by implanting the impurity of the first conductive type into the interior organization of the active area; and (g) forming a drain area above and apart from the charge accumulating area by implanting the impurity of the first conductive type.

### BRIEF DESCRIPTIONS OF THE DRAWINGS

FIG. 1 is a circuit structure diagram showing the structure of a light receiving portion in the image sensor according to the first embodiment of the present invention;

FIG. 2 is a plan view showing a part of the light receiving portion of the image sensor according to the first embodiment;

FIG. 3 is a sectional view taken along the line A-A of FIG. 2;

FIG. 4 is a sectional view showing the manufacturing process of the solid-state imaging device of the first embodiment of the present invention;

FIG. 5 is a sectional view showing the manufacturing process of the solid-state imaging device continued from FIG. 4;

FIG. 6 is a sectional view showing the manufacturing process of the solid-state imaging device continued from FIG. 5;

FIG. 7 is a sectional view showing the manufacturing process of the solid-state imaging device continued from FIG. 6;

FIG. 8 is a sectional view showing the manufacturing process of the solid-state imaging device continued from FIG. 7;

FIG. 9 is a sectional view showing the manufacturing process of the solid-state imaging device continued from FIG. 8;

FIG. 10 is a plan view showing a part of the light receiving portion of the image sensor according to a second embodiment;

FIG. 11 is a sectional view taken along the line A-A of FIG. 10;

FIG. 12 is a sectional view showing the manufacturing process of the solid-state imaging device according to the second embodiment of the present invention;

FIG. 13 is a sectional view showing the manufacturing process of the solid-state imaging device continued from FIG. 12;

FIG. 14 is a sectional view showing the manufacturing process of the solid-state imaging device continued from FIG. 13;

FIG. 15 is a sectional view showing the manufacturing process of the solid-state imaging device continued from FIG. 14;

FIG. 16 is a sectional view showing the manufacturing process of the solid-state imaging device continued from FIG. 15;

FIG. 17 is a plan view showing a part of the light receiving portion of the image sensor according to the third embodiment;

FIG. 18 is a sectional view taken along the line A-A of FIG. 17;

FIG. 19 is a sectional view showing the manufacturing process of the solid-state imaging device according to the third embodiment of the present invention;

FIG. 20 is a sectional view showing the manufacturing process of the solid-state imaging device continued from FIG. 19;

FIG. 21 is a sectional view showing the manufacturing process of the solid-state imaging device continued from FIG. 20; and

FIG. 22 is a sectional view showing the manufacturing process of the solid-state imaging device continued from FIG. 21.

### DESCRIPTION OF THE PREFERRED EMBODIMENTS

Hereinafter, the preferred embodiments of the present invention will be described in detail with reference to the accompanying drawings. Like reference numerals are attached to components having the same function throughout all drawings for explaining the embodiments and repeated description thereof is omitted.

In the embodiments described below, the present invention is applied to an image sensor (solid-state imaging device) having a plurality of cells including the photo diode and the metal insulator semiconductor (MIS) transistor for transmission.

### First Embodiment

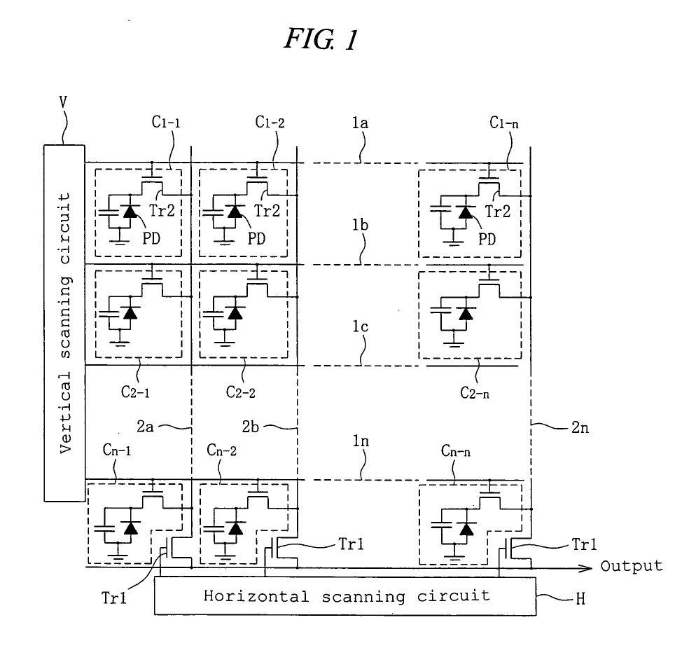

The image sensor according to this embodiment will be described with reference to the accompanying drawings. FIG. 1 is a circuit structure diagram showing the structure of the light receiving portion in the image sensor of the first embodiment. Referring to FIG. 1, the image sensor of the first embodiment contains a vertical scanning circuit V and a horizontal scanning circuit H.

Scanning lines (pixel selecting lines) 1a-1n are connected to a vertical scanning circuit V and the vertical scanning circuit V is capable of applying voltages (pulses) onto these scanning lines 1a-1n.

The n-number of wires are connected to the horizontal scanning circuit H and each wire is connected to the gate electrode of the MIS transistor Tr1. Then, the horizontal scanning circuit H is capable of applying voltages to the gate electrodes of the n-numbers of MIS transistors Tr1 successively. One of the scanning lines 2a-2n is connected to the source area of each MIS transistor Tr1 and a common output line is connected to the drain area of each MIS transistor.

The scanning lines 1a-1n and the scanning lines 2a-2n are disposed such that they intersect each other at right angle without being connected. Cells C₁₋₁, C₁₋₂, . . . C₁₋ₙ, C₂₋₁, . . . Cₙ₋ₙ are formed in individual cells (pixels) sectioned by the scanning lines 1a-1n and the scanning lines 2a-2n.

The cell Cᵣ₋ₛ (1≦r≦n, 1≦s≦n; r, s are natural numbers) forms a minimum unit of the light receiving portion of the image sensor, including the photo diode PD and the MIS transistor Tr2.

The photo diode PD generates electric charges by converting light inputted to the image sensor from an object photo-electrically and accumulates the generated electric charges. The MIS transistor Tr2 acts as a switch for transferring the electric charges accumulated in the photo diode PD outside of the cell Cᵣ₋ₛ.

In each cell Cᵣ₋ₛ, one end of the photo diode PD is grounded while the other end thereof is electrically connected to the source electrode of the MIS transistor Tr2. The drain area of each MIS transistor Tr2 is connected to the scanning lines 2a-2n and the gate electrode of each MIS transistor Tr2 is connected to one of the scanning lines 1a-1n extracted from the vertical scanning circuit V.

In the meantime, the capacitor connected in parallel to the photo diode PD does not exist actually but accumulation of electric charges in the photo diode PD is expressed as an equivalent circuit.

Next, the operation of the image sensor having such a structure will be described briefly. First, an operation for accumulating an electric charge corresponding to light incident from an object in the image sensor will be described.

When light from the object impinges upon the photo diode PD in each cell Cᵣ₋ₛ, light is converted to electric charge photo-electrically and the gained electric charge is accumulated in the photo diode PD. The electric charge accumulated in the photo diode is of an quantity corresponding to the intensity of light impinging upon the photo diode PD and the accumulating time.

Next, the operation for outputting electric charge accumulated in the photo diode PD will be described.

A pulse voltage is applied to the scanning lines 1a-1n successively by the vertical scanning circuit V. Assume that currently a pulse voltage is applied to a specific scanning line 1r. At this time, no voltage is applied to other scanning lines. Then, cells Cᵣ₋₁, Cᵣ₋₂, . . . Cᵣ₋ₙ connected to the scanning line 1r are selected, so that a voltage is applied to the gate electrode of each MIS transistor Tr2. If a voltage is applied to each gate electrode, each MIS transistor Tr turns ON, so that electric charge accumulated in each photo diode PD of the cells Cᵣ₋₁, Cᵣ₋₂, . . . Cᵣ₋ₙ is fetched out to the scanning lines 2a-2n. For example, the electric charge accumulated in the photo diode PD of the cell Cᵣ₋₁ is fetched out to the scanning line 2a and the electric charge accumulated in the photo diode of the cell Cᵣ₋₂ is fetched out to the scanning line 2b.

Next, the horizontal scanning circuit H applies pulse voltage to the gate electrodes of n-numbers of MIS transistors Tr1 successively. For example, the MIS transistor Tr1 connected to the scanning line 2a is turned ON first. When the MIS transistor Tr1 connected to the scanning line 2a is turned ON, respective MIS transistors Tr1 connected to the other scanning lines 2b-2n remain OFF.

When the MIS transistor Tr1 connected to the scanning line 2a is turned ON, the scanning line 2a and output line becomes conductive, so that electric charge fetched out to the scanning line 2a (electric charge accumulated in the cell Cᵣ₋₁) is outputted through the output line.

Subsequently, if the MIS transistor Tr1 connected to the scanning line 2b is turned ON by the horizontal scanning circuit H, the scanning line 2b and the output line become conductive, so that electric charge fetched out to the scanning line 2b (electric charge accumulated in the cell Cᵣ₋₂) is outputted through the output line.

In this way, the horizontal scanning circuit H continues the operation until it outputs electric charge fetched out to the scanning line 2n (electric charge accumulated in the cell Cᵣ₋ₙ).

After that, the application of voltage to the scanning line 1r is terminated by the vertical scanning circuit V and next, a voltage is applied to a scanning line 1 (r+1) and the above-described operation is repeated. All electric charges in the cells Cᵣ₋ₛ arranged two-dimensionally are outputted. After an electric signal corresponding to the outputted electric charge is amplified by an amplifier, the amplified electric signal is inputted to, for example, a display unit. Consequently, an image is represented on the display.

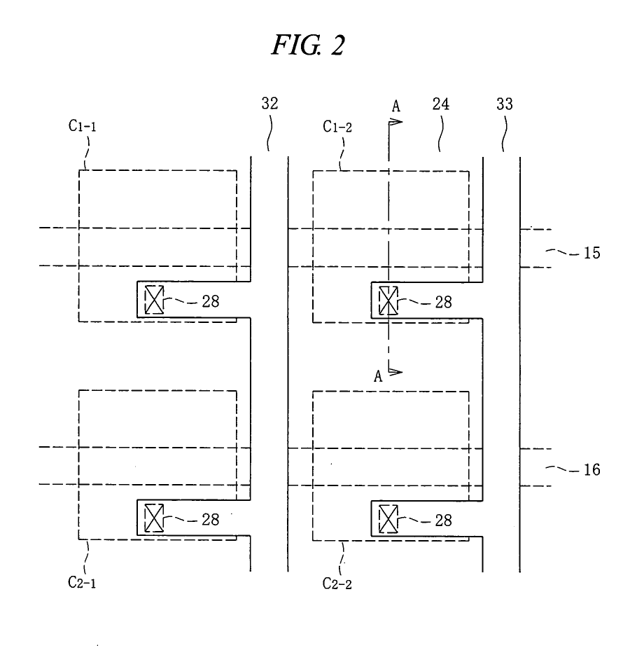

Next, the actual configuration of the image sensor of the first embodiment will be described. FIG. 2 is a plan view of an area in the vicinity of the cells C₁₋₁, C₁₋₂, C₂₋₁, C₂₋₂ formed on the semiconductor substrate as seen from above. Referring to FIG. 2, wires 32, 33 are formed on an interlayer insulating film 24 so that they extend from up in this paper to down. This wire 32 is connected to the scanning line 2a shown in FIG. 1 or the wire 32 is just the scanning line 2a. Likewise, the wire 33 is connected to, for example, the scanning line 2b or the wire 33 is just the scanning line 2b.

An L-shaped extracted line is formed from each of the wires 32, 33 and an end of this extracted line is connected to a plug 28 going through the interlayer insulating film 24.

As indicated with dotted lines, the cells C₁₋₁, C₁₋₂, C₂₋₁, C₂₋₂ are formed under the interlayer insulating film 24. The cell C-₁₋₁ is formed on the top left side while the cell C₁₋₂ is formed on the top right side. Further, the cell C₂₋₁ is formed on the bottom left side while the cell C₂₋₂ is formed on the bottom right. These cells C₁₋₁-C₂₋₂ and the wires 32, 33 are connected electrically through the plugs 28 going through the interlayer insulating film 24. For example, the cell C₁₋₁ is connected electrically to the wire 32 in a bottom area of the cell C₁₋₁ and the cell C₁₋₂ is connected electrically to the wire 33 in a bottom area of the cell C₁₋₂. The cells C₁₋₁-C₂₋₂ shown in FIG. 2 correspond to those having the same reference numerals shown in FIG. 1.

A gate electrode 15 is formed in the cells C₁₋₁, C₁₋₂ such that it traverses the central area of each. Likewise, a gate electrode 16 is formed in the cells C₂₋₁, C₂₋₂ such that it traverses the central area of each. These gate electrodes 15, 16 are formed in the lower layer of the interlayer insulating film 24, such that they are disposed intersecting the wires 32, 33. Then, the gate electrode 15 is connected electrically to the scanning line 1a shown in FIG. 1 or it is just the scanning line la. Likewise, the gate electrode 16 is connected electrically to the scanning line 1b shown in FIG. 1 or it is just the scanning line 1b.

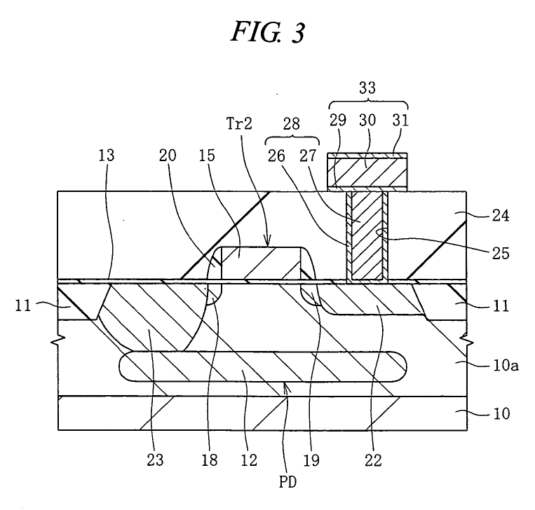

FIG. 3 shows a sectional view taken the line A-A of FIG. 2 and the structure of the cell C₁₋₂ will be described with reference to FIG. 3.

As shown in FIG. 3, a isolation area 11 for separating the cell C₁₋₂ from the other cell Cᵣ₋ₛ is provided on the semiconductor substrate 10 and a p-type well 10a is formed in an activate area between these isolation areas 11. The cell C₁₋₂ of the first embodiment is formed on this p-type well 10a.

In the cell C₁₋₂ of the first embodiment, the MIS transistor Tr2 for transferring electric charge is formed on the surface of the semiconductor substrate 10 and a charge accumulating area 12 which constitutes a part of the photo diode PD is formed in the lower layer of this MIS transistor Tr2, that is, within the semiconductor substrate 10 (within the p-type well 10a).

The p-type impurity, for example, boron or boron fluoride, is implanted into the semiconductor substrate 10 and the p-type well 10a and the n-type impurity, for example, phosphorous or arsenic, is implanted into the charge accumulating area 12. Thus, pn junction is formed in the vicinity of the boundary between the p-type well 10a and the charge accumulating area 12 and pn junction type photo diode PD is formed by this p-type well 10a and the charge accumulating area 12. Thus, when light impinges upon the vicinity of the pn junction, electrons are generated due to photo-electric effect and the generated electrons are accumulated in the n-type semiconductor area (charge accumulating area 12) having a low energy level.

The charge transferring MIS transistor Tr2 is formed above this charge accumulating area 12 and has a following structure. That is, a gate insulating film 13 is formed on the semiconductor substrate 10 and a gate electrode 15 is formed on this gate insulating film 13. A side wall 20 is formed on the side wall of this gate electrode 15 in order for the source area and drain area to be lightly doped drain (LDD) structure. Low density n-type impurity diffusion areas 18, 19 are formed in the semiconductor substrate 10 (in p-type well 10a) just below the side wall 20 and high density n-type impurity areas 22, 23 are formed outside of the low density n-type impurity diffusion areas 18, 19. The source area of the MIS transistor Tr2 is formed of this low density n-type impurity diffusion area 18 and the high density n-type impurity diffusion area 23, and the drain area of the MIS transistor Tr2 is formed of the low density n-type impurity diffusion area 19 and the high density n-type diffusion area 22. Further, the p-type well 10a is formed in the semiconductor substrate 10 just below the gate electrode 15. Therefore, the channel area of the MIS transistor Tr2, which is a n-type MIS transistor, serves as a p-type semiconductor area. For the reason, increase in leakage current can be suppressed more as compared to a case where the channel area is formed with n-type MIS transistor as an n-type semiconductor area, thereby preventing read-out charge from being decreased.

In the cell C₁₋₂ of the first embodiment having such a structure, when the charge accumulating area 12 is projected onto the device formation plane (surface) of the semiconductor substrate 10, it is so constructed that there exists an overlapping area between the drain area and the charge accumulating area 12 while the gate electrode 15 of the MIS transistor Tr2 is formed above and apart from the charge accumulating area 12. Therefore, when the gate electrode 15 and the charge accumulating area 12 are projected onto the device formation plane of the semiconductor substrate 10, it is apparent that both of them have an overlapping area.

The high density n-type impurity diffusion area 23 (source area) is electrically connected to the charge accumulating area 12 buried in the semiconductor substrate 10. Because the source area of the MIS transistor Tr2 and the charge accumulating area 12 are connected electrically, when the MIS transistor Tr2 is turned ON, electrons accumulated in the charge accumulating area 12 can be transferred from the source area of the MIS transistor Tr2 to the drain area. On the other hand, when the MIS transistor Tr2 is turned OFF, electric charge can be accumulated in the charge accumulating area 12. Although this high density n-type impurity diffusion area 23 acts as a source area of the MIS transistor Tr2, this is a semiconductor area formed by implanting the same n-type impurity as the charge accumulating area 12 and in contact with the charge accumulating area 12. Thus, the high density n-type impurity diffusion area 23 can be considered as a part of the charge accumulating area 12. From this, it can be expressed that although the broadly-defined charge accumulating area is comprised of mainly an area (charge accumulating area 12) extending substantially in parallel to the surface of the semiconductor substrate formed by implanting the n-type impurity (first conductive impurity) into the inside of the semiconductor substrate, a part thereof extends so as to be exposed on the surface of the semiconductor substrate (as the high density n-type impurity diffusion area 23). That is, the broadly-defined charge accumulating area includes the charge accumulating area 12 and the high density n-type impurity diffusion area 23.

As seen from this, it can be expressed that the source area of the MIS transistor Tr2 is connected to a portion (high density n-type impurity diffusion area 23) extending to the surface of the semiconductor substrate in the charge accumulating area and the gate electrode 15 is provided above the area adjacent to that portion extending to the surface of the semiconductor substrate in the charge accumulating area exposed on the surface of the semiconductor substrate.

No p-type high density impurity area is formed on the surface of the high density n-type impurity diffusion area 23 unlike the conventional technology. Thus, the n-type area in the vicinity of the surface is never narrowed. Thus, delay in the charge transmission speed can be prevented.

Next, the interlayer insulating film 24 is formed over the charge transferring MIS transistor Tr2 and a connecting hole 25 is formed in this interlayer insulating film 24 so that a drain area (high density n-type impurity diffusion area 22) is exposed outside.

Then, this connecting hole is filled with titan/titan nitride film 26 and tungsten film 27 so as to form the plug 28. This plug 28 is connected electrically to the wire 33 on its top. This plug 28 acts for connecting the drain area to the wire 33 electrically. The wire 33 is formed of a laminated film of, for example, titan/titan nitride film 29, aluminum film 30 and titan/titan nitride film 31. Meanwhile, although an example that the wire 33 is formed of the aluminum film 30 has been indicated here, it may be formed of, for example, copper wire.

According to the cell C₁₋₂ of the first embodiment having the above-described structure, the area of the cell C₁₋₂ can be reduced to a smaller than conventionally by disposing the charge transferring MIS transistor Tr2 and the charge accumulating area 12 in a vertical direction. That is, conventionally, the lateral structure in which the charge accumulating area 12 is disposed sideway of the charge transferring MIS transistor Tr2 is adopted. Such a lateral structure increases the area of the cell, thereby making it impossible to improve the resolution of the image sensor. However, because in the cell C₁₋₂ of the first embodiment, the charge transferring MIS transistor Tr2 and charge accumulating area 12 are constructed in a vertical structure as described above, the area of the cell C₁₋₂ can be reduced relatively.

Although the gate electrode 15 of the MIS transistor Tr2 above the charge accumulating area 12 is considered to intercept incident light to the photo diode PD, there exists no problem because the gate electrode 15 is formed of polysilicon film having transparency. However, although a portion in which the wire 33 made of metal is formed above the charge accumulating area 12 is shielded from the incident light, this is no problem because the shielded area (area corresponding to the extracted line of the wire 33) is small with respect to the entire area of the cell C₁₋₂. Therefore, according to the cell C₁₋₂ of the first embodiment, the size of the cell C₁₋₂ can be reduced while maintaining the same light receiving area as when a lateral structure is adopted.

Further, because according to the cell C₁₋₂ of the first embodiment, the charge accumulating area 12 which is a major area for accumulating electric charge is not in contact with the surface (device formation side) of the semiconductor substrate 10 and the gate insulating film 13, the leakage current due to a defect in the surface can be reduced. That is, when there is much leakage current, electric charge is accumulated, thereby increasing noise even when no light is projected to the photo diode PD. Particularly, in the case where the size of the cell 1-2 is decreased only, the quantity of incident light decreases so that an influence of the leakage current increases. However, because according to the cell C₁₋₂ of the first embodiment, the size of the cell C₁₋₂ is reduced while almost maintaining the light receiving area, the influence of the leakage current is not increased so much. Further, because the charge accumulating area 12 is provided not on the surface of the semiconductor substrate but inside thereof, it is not affected by a defect in the surface thereby reducing the leakage current. That is, in the cell C₁₋₂ of the first embodiment, the resolution can be improved by double effects by reducing of the cell area while maintaining the light receiving area and reducing of the leakage current.

Further, because the size of the cell C₁₋₂ of this embodiment can be reduced, the quantity of the image sensors formed on a wafer can be increased. Therefore, the price of each image sensor can be reduced and production cost can be reduced.

Next, a manufacturing method of the image sensor of the first embodiment will be described with reference to the drawings.

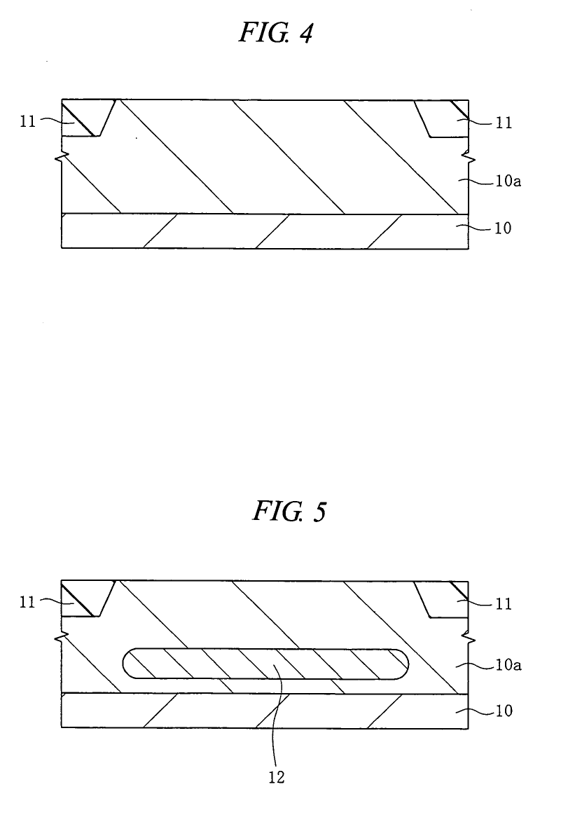

First, a semiconductor substrate 10 obtainable with the p-type impurity being implanted into, for example, mono-crystal silicon is prepared as shown in FIG. 4. As the p-type impurity, for example, boron, boron fluoride and the like are available. Next, the isolation areas 11 are formed in the device formation side of this semiconductor substrate 10. The purpose of the provision of the isolation areas 11 is to electrically separate the cells Cᵣ₋ₛ to each other to block the interference among the cells. The isolation areas 11 can be formed according to, for example, local oxidation of silicon (LOCOS) method or shallow trench isolation (STI) method. FIG. 4 shows a case that the isolation areas 11 are formed according to the STI method, in which grooves of, for example, about 300 nm are dug in the device formation side of the semiconductor substrate 10 employing etching technology and then, the grooves are filled with silicon oxide according to the CVD method and after that, the device formation side of the semiconductor substrate 10 is polished according to chemical mechanical polishing (CMP) method. The STI method enables not only the separating width to be narrower than the LOCOS method but also the isolation area 11 to be deeper, thereby achieving higher integration of the device.

Subsequently, the p-type well 10a is formed in the activate area separated by the isolation areas 11. The p-type well 10a can be formed by implanting boron or boron fluoride, which is a p-type impurity according to photo lithography technology or ion implantation method.

Next, the device formation side of the semiconductor substrate 10 is coated with resist film and then, that resist film is patterned by exposing to light and developing. The patterning is carried out such that the light receiving area of the cell Cᵣ₋ₛ is open. Then, by implanting the n-type impurity into the inside organization (specifically, inside the p-type well 10a) of the semiconductor substrate 10 according to the ion implantation method, the charge accumulating area 12 which has no contact portion with the device formation side of the semiconductor substrate 10 is formed. The ion plantation for forming the charge accumulating area 12 is carried out by implanting for example, phosphorous at a dose amount of about 2.0×10¹³/cm² with an energy of about 200 keV. The charge accumulating area 12 can be formed as an area not in contact with the device formation area (surface) of the semiconductor substrate 10 because it is formed by implanting phosphorous under a relatively high energy. For example, the charge accumulating area 12 is formed about 0.1 μm to about 1 μm deep from the device formation side of the semiconductor substrate 10.

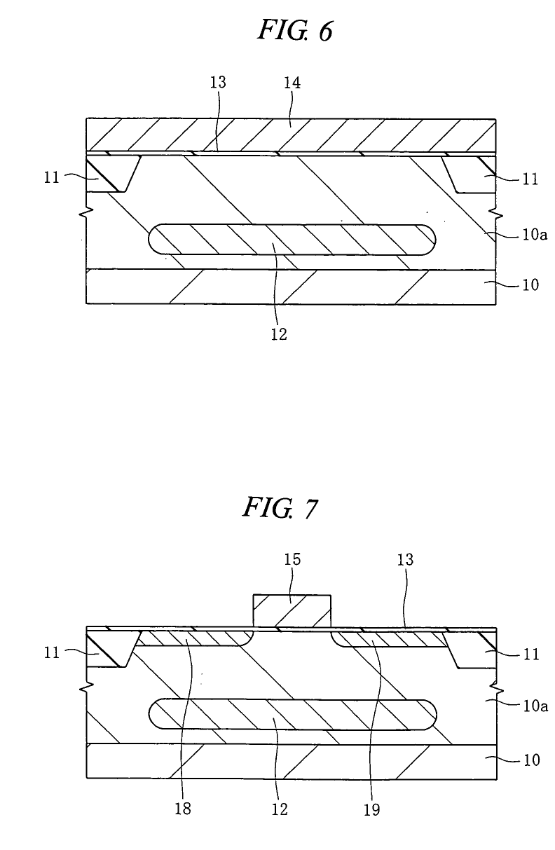

Subsequently, the gate insulating film 13 is formed on the device formation side of the semiconductor substrate 10 as shown in FIG. 6. The gate insulating film 13 is comprised of, for example, silicon oxide film and can be formed, for example, according to thermal oxidation method. More specifically, the gate insulating film 13 can be formed by dry oxidation of, for example, about 900° C.

Conventionally, as the gate insulating film 13, silicon oxide film is used from the viewpoints that the gate insulating film 13 has a high dielectric strength, suffers from a small leakage current and the electric/physical stability of silicon-silicon oxide interface is excellent.

However, with progress in fineness of the device, thinning of the gate insulating film 13 has been demanded. When such a thin gate oxide film is used, so-called tunnel current phenomenon occurs that electrons flowing through a channel in the MOS transistor flows to the gate electrode tunneling a barrier formed with silicon oxide film.

Then, it has come to use high-k film in which the physical film thickness can be increased by using a material having a higher dielectric constant than silicon oxide. Therefore, the gate insulating film 13 may be formed from for example, aluminum oxide, hafnium oxide, zirconium oxide, or silicon nitride.

Subsequently, the polysilicon film 14, which is a conductive film, is formed on the gate insulating film 13. To form the polysilicon film 14, it is permissible to use the chemical vapor deposition (CVD) method that by decomposing thermally silane gas in nitrogen gas, polysilicon film 14 is deposited. When polysilicon film 14 is deposited, conductive impurity such as phosphorous is added to reduce the resistance of the gate electrode 15, which will be described later. Further, the conductive impurity may be added after the polysilicon film 14 is formed.

Next, photo-sensitive resist film is applied to the polysilicon film 14. To apply the resist film, for example, spin coating method can be used. Then, a mask pattern is transferred to the resist film using an exposure device. By developing the resist film to which the mask pattern is transferred, a patterned resist film is formed. When patterning, the resist film is left in an area in which, for example, the gate electrode is formed. Then, by etching with the patterned resist film as a mask, the gate electrode 15 shown in FIG. 7 is formed.

Subsequently, the low density n-type impurity diffusion areas 18, 19 are formed according to the ion implantation method with the gate electrode 15 as a mask. The ion implantation for forming the low density n-type impurity diffusion areas 18, 19 is carried out by implanting, for example, phosphorous at a dose amount of about, 2.0×10¹³/cm² with an energy of about 60 keV.

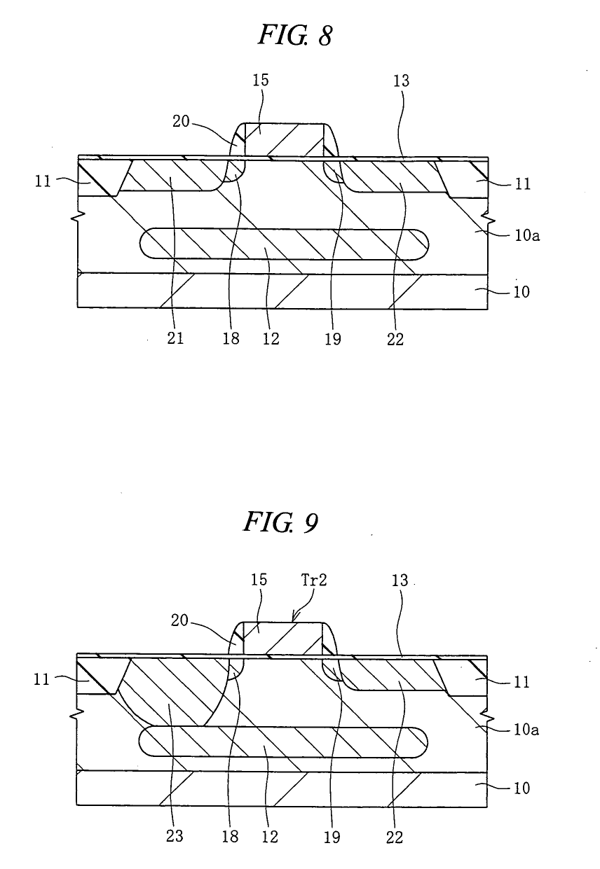

Next, silicon nitride is formed on the device formation side of the semiconductor substrate 10. The silicon nitride can be formed according to, for example, the CVD method. Then, by anisotropic-etching this silicon nitride film, the side walls 20 are formed on both sides of the gate electrode 15 as shown in FIG. 8. Meanwhile, the side walls 20 may be formed of silicon oxide film by anisotropic-etching the silicon oxide film formed on the semiconductor substrate 10.

Next, the high density n-type impurity diffusion areas 21, 22, which are semiconductor areas, are formed using photo lithography technology and ion implantation method as shown in FIG. 8. The ion implantation for forming the high density n-type impurity diffusion areas 21, 22 is carried out by implanting, for example, arsenic at a dose amount of about 1.0×10¹⁵/cm² with an energy of about 60 keV.

Subsequently, after resist film is coated on the semiconductor substrate 10, the resist film is patterned by exposing to light and developing. When patterning, the source area (high density n-type impurity diffusion area 21) is kept open. After that, by implanting phosphorous which is n-type impurity, into the semiconductor substrate 10 according to the ion implantation method, the high density n-type impurity diffusion area 23, which is conductive with the charge accumulating area 12, is formed as shown in FIG. 9. The ion implantation is carried out by implanting phosphorous at a dose amount of about 1.0×10¹⁴/cm² with an energy of about 200 keV.

Consequently, the charge accumulating area 12 is formed within the semiconductor substrate 10 and then, the charge transferring MIS transistor Tr2 is formed above this charge accumulating area 12. Further, because the gate electrode 15 of the MIS transistor Tr2 is formed of polysilicon film 14 having transparency, it is possible to reduce the area of the cell Cᵣ₋ₛ while maintaining the light receiving area of the cell r-s.

Next, the wiring process will be described. The interlayer insulating film 24 is formed on the device formation side of the semiconductor substrate 10 as shown in FIG. 3. The interlayer insulating film 24 is comprised of, for example, silicon oxide and can be formed according to, for example, the CVD method. Then, the surface of the interlayer insulating film 24 is flattened. For the flattening of the surface, for example, the CMP method is available.

Next, the connecting hole 25 is formed in the interlayer insulating film 24 using photo lithography technology and etching technology. The high density n-type impurity diffusion area 22 is exposed on the bottom of the connecting hole 25. Subsequently, the titan/titan nitride film 26 is formed on the entire device formation side of the semiconductor substrate 10. The titan/titan nitride film 26 can be formed according to, for example, spattering method and is formed also on the inner wall and bottom of the connecting hole 25. This titan/titan nitride film 26 has the function to block the tungsten film 27 to be buried into the connecting hole 25 from diffusion into the silicon.

Subsequently, the tungsten film 27 is formed on the titan/titan nitride film 26. This tungsten film 27 is formed such that the connecting hole 25 is filled therewith, and can be formed according to, for example, the CVD method. After that, unnecessary titan/titan nitride film 26 and the tungsten film 27 formed except in the connecting hole 25 are removed according to, for example, the CMP method so as to form the plug 28.

Subsequently, the titan/titan nitride film 29, the aluminum film 30 and the titan/titan nitride film 31 are formed successively. These films can be formed according to, for example, spattering method. After that, the above-described films are patterned using photo-lithography technology and etching technology so as to form the wire 33.

In such a way, the first layer wire is formed. Although the multi-layer wires are formed in a subsequent process in the same way, description thereof is omitted.

In the cell C₁₋₂ of this embodiment, the source area (low density n-type impurity diffusion area 18 and high density n-type impurity diffusion area 23) is formed in contact with the surface of the semiconductor substrate 10 and the isolation area 11. In this case, although the leakage current can be reduced as compared to when the charge accumulating area 12 is formed on the surface of the semiconductor substrate 10, because the source area electrically connected to the charge accumulating area 12 is formed on the surface, the charge accumulating area is affected by a defect in the surface, so that a slight leakage current flows out. Therefore, from the viewpoint of reducing the leakage current further, it is desirable to form the source area of the MIS transistor Tr2 not to be in contact with the surface of the semiconductor substrate 10 and the isolation area 11.

### Second Embodiment

Although the gate electrode 15 of the MIS transistor Tr2 according to the first embodiment is formed above and apart from the charge accumulating area 12, according to the second embodiment of the present invention, the cell Cᵣ₋ₛ in which the gate electrode is formed within the device separating groove will be described with reference to the accompanying drawings.

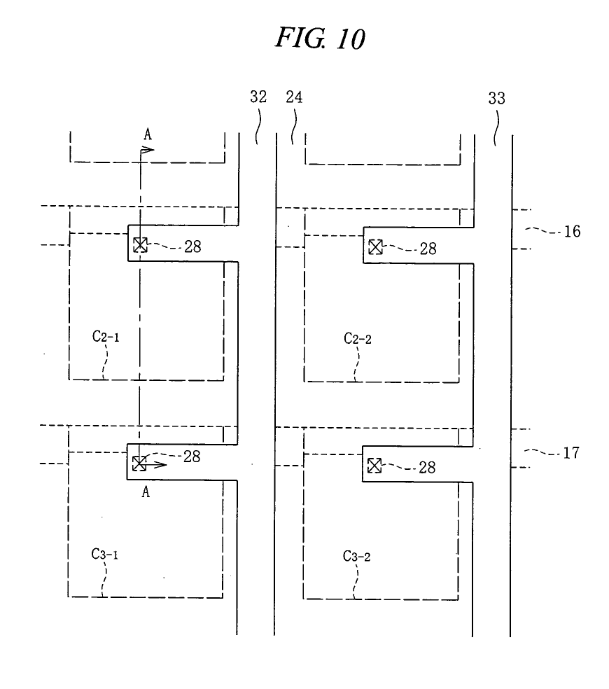

FIG. 10 is a plan view of a part of the light receiving portion of the image sensor of the second embodiment as seen from above. In the light receiving portion of the image sensor, as described already about the first embodiment, the cells Cᵣ₋ₛ (1≦r≦n, 1≦s≦n; r, s are natural numbers) are arranged two-dimensionally and wires for connecting these cells electrically are disposed longitudinally and laterally.

Referring to FIG. 10, wires 32, 33 are formed on the interlayer insulating film 24 and these wires 32, 33 are formed in parallel to each other from up to down of this paper. The wires 32, 33 are provided with extracted lines and the wires 32, 33 are connected electrically to the plug 28 at the respective ends of the extracted lines. The wires 32, 33 are connected electrically to the scanning lines 2a, 2b shown in FIG. 1 or they are just the scanning lines 2a, 2b.

The plugs 28 go through the interlayer insulating film 24 and are connected to the cells C₂₋₁, C₃₋₁, C₂₋₂, C₃₋₂ formed under the interlayer insulating film 24. The gate electrode 16 or gate electrode 17 is formed in the cells C₂₋₁-C₃₋₂ and the gate electrodes 16, 17 are formed intersecting the wires 32, 33 at right angle. The gate electrodes 16, 17 are not formed to traverse the central portion of the cell Cᵣ₋ₛ as indicated in the first embodiment, but formed at the ends of the cell Cᵣ₋ₛ.

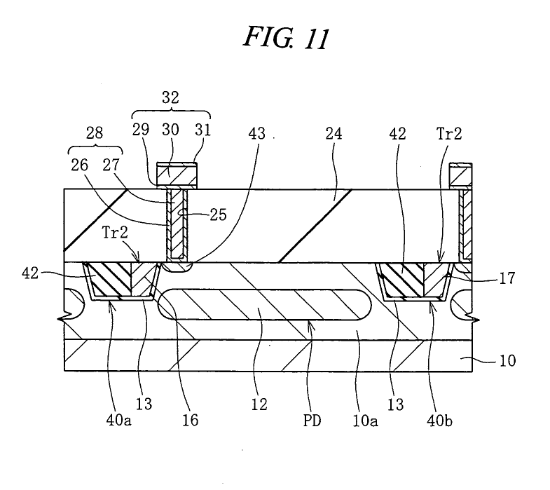

FIG. 11 shows a sectional view taken along the line A-A of FIG. 10. Referring to FIG. 11, grooves 40a, 40b are formed in the semiconductor substrate 10 and the charge transferring MIS transistor Tr2 for the cell C₂₋₁ is formed within the groove 40a and in a part of an activate area (area between the groove 40a and the groove 40b). Further, likewise, the charge transferring MIS transistor Tr2 for the cell C₃₋₁ is formed within the groove 40b and in a part of the activate area, although description thereof is omitted.

The p-type well 10 is formed within the activate area between the groove 40a and the groove 40b and the charge accumulating area, which is an n-type semiconductor area, is formed in this p-type well 10a. This charge accumulating area 12 is not in contact with the groove 40a or the groove 40b. Because the charge accumulating area 12 of the photo diode PD is formed within the semiconductor substrate 10 and the charge accumulating area 12 is not in contact with the grooves 40a, 40b, an influence of a defect in the surface can be suppressed thereby reducing a leakage current.

Hereinafter, the structure of the charge transferring MIS transistor Tr2 of the second embodiment will be described.

The gate insulating film 13 is formed on the sides and bottom of the groove 40a and the gate electrode 16 and the isolation area 42 are formed within the groove 40a having this gate insulating film 13 so that the groove 40a is filled. That is, the gate electrode 16 and the isolation area 42 are formed on a side and a part of the bottom of the groove 40a. Then, a high density n-type impurity diffusion area (drain area) 43 is formed in a part of an area adjacent to the groove 40a. This high density n-type impurity diffusion area 43 is formed above and apart from the charge accumulating area 12. In other words, when this charge accumulating area 12 is projected to the surface of the activate area, it is so provided to have an area overlapping this high density n-type impurity diffusion area 43.

The MIS transistor Tr2 of the cell C₂₋₁ is comprised of the gate insulating film 13 formed on the side of the groove 40a, the gate electrode 16 formed so as to fill a part of the groove 40a, the charge accumulating area 12 and the high density n-type impurity diffusion area 43. That is, the MIS transistor Tr2 of the second embodiment is capable of transferring electrons from the charge accumulating area 12 which is to be the source area to the high density n-type impurity diffusion area 43 as the drain area by means of the gate electrode 16 formed within the groove 40a.

In the cell C₂₋₁ of the second embodiment, the charge accumulating area 12 can be used as the MIS transistor Tr2 because the charge transferring MIS transistor Tr2 is provided in a vertical structure. While in the cell Cᵣ₋ₛ of the first embodiment, the charge transferring MIS transistor Tr2 is provided in a lateral structure as shown in FIG. 3 and the source area and drain area are formed in the surface (device formation side) of the semiconductor substrate 10. Thus, the high density n-type impurity diffusion area 23 (a part of the source area) is provided so as to be electrically connected to the charge accumulating area 12 formed in the p-type well 10a. However, although with this structure, the charge accumulating area 12 is buried in the p-type well 10a, the high density n-type impurity diffusion area 23 electrically connected to the charge accumulating area 12 is in contact with the surface of the semiconductor substrate 10. Thus, the charge accumulating area 12 comes to be indirect contact with the surface of the semiconductor substrate 10 through the high density n-type impurity diffusion area 23, so that a slight amount of leakage current may be generated in the surface. However, according to the second embodiment, the charge accumulating area 12 buried in the p-type well 10a itself can be the source area of the MIS transistor Tr2, so that the generation of the leakage current due to an influence of the surface can be prevented.

Further, the charge accumulating area 12 (photo diode PD) and the charge transferring MIS transistor Tr2 are provided in a vertical structure, so that the cell size can be reduced as compared to the conventional structure while maintaining the light receiving area.

In case of the first embodiment, the lateral type MIS transistor Tr2 is formed in the surface area of the charge accumulating area 12. Thus, the light receiving surface (cell size) is restricted by the size of the MIS transistor. That is, the source area, the gate area 15 and the drain area need to be formed in the surface of the semiconductor substrate 10, so that the light receiving surface (activate area) can not be reduced to be smaller than the size of these combined areas. Contrary to this, in case of the second embodiment, the gate electrode 16 is provided within the groove 40a and the source area is just the charge accumulating area 12. Therefore, it comes that only the high density n-type impurity diffusion area 43, which is a drain area, is formed on the surface of the semiconductor substrate 10, thereby the cell size can be reduced as compared to the first embodiment.

Further, because the cell size can be reduced, the quantity of the image sensors which can be formed on the wafer can be increased. Therefore, the price of each image sensor can be reduced and the production cost also can be reduced.

Next, the interlayer insulating film 24 is formed over the semiconductor substrate 10 and the connecting hole (contact hole) 25 is formed in this interlayer insulating film 24. The connecting hole 25 goes through the interlayer insulating film 24 and its bottom portion reaches the high density n-type impurity diffusion area 43, which is a drain area.

The titan/titan nitride film 26 and the tungsten film 27 are buried in the connecting hole 25 so as to form the plug 28. Then, the wire 32 comprised of laminated films successively having the titan/titan nitride film 29, the aluminum film 30 and titan/titan nitride film 31 is formed on the plug 28.

Each cell Cᵣ₋ₛ of the image sensor of the second embodiment is provided with the above-described structure and hereinafter, the manufacturing method of the image sensor will be described with reference to the accompanying drawings.

First, for example, a semiconductor substrate 10 obtainable with p-type impurity being implanted into a mono-crystal silicon is prepared. As the p-type impurity to be implanted, for example, boron, boron fluoride and the like are available.

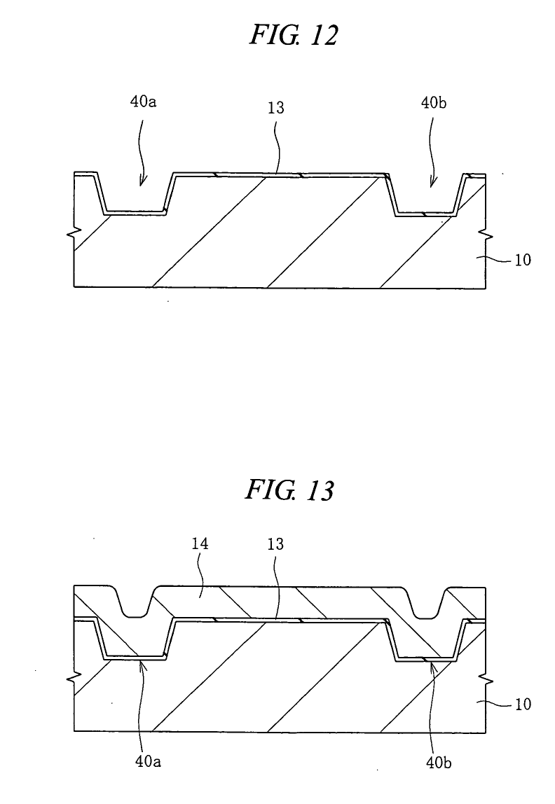

Next, a groove 40a and a groove 40b are formed in the device formation surface of the semiconductor substrate 10 using photo lithography technology and etching technology as shown in FIG. 12. The grooves 40a, 40b are formed to have about 300 nm deep. Subsequently, the gate insulation film (first insulation film) 13 is formed on the device formation side of the semiconductor substrate 10. The gate insulation film 13 is comprised of, for example, silicon oxide film and can be formed according to, for example, thermal oxidation method. At this time, silicon oxide film is formed on the sides and bottom of the grooves 40a, 40b.

In the meantime, as the gate insulation film 13, it is permissible to use high-k film which has a higher dielectric constant than the silicon oxide film and enables physical film thickness to be increased as described previously about the first embodiment. As the high-k film, for example, aluminum oxide film, hafnium oxide film, zirconium oxide film, silicon nitride and the like are available.

Next, polysilicon film (first conductive film) 14 is formed on the semiconductor substrate 10 as shown in FIG. 13. The polysilicon film 14 can be formed according to, for example, CVD method and then, formed so as to fill the grooves 40a, 40b formed in a previous process. To reduce the resistance of the gate electrodes 16, 17, which will be described later, conductive impurity such as phosphorus is added when polysilicon film 14 is deposited.

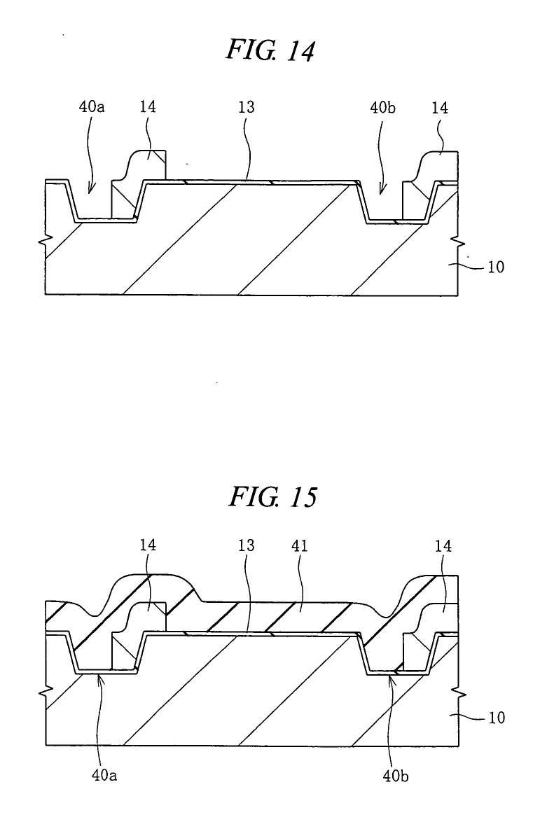

Successively, light sensitive resist film is applied onto the formed polysilicon film 14, and then this resist film is patterned by exposing to light and developing. Upon patterning, the resist film is left partially within the grooves 40a, 40b and in an area out of the grooves 40a, 40b. Then, the polysilicon film 14 is patterned with the patterned resist film as a mask as shown in FIG. 14.

The gate electrodes 16, 17, comprised of the polysilicon film 14, which will be described later, are formed only within the grooves 40a, 40b. Therefore, it may be considered that the polysilicon film 14 would not need to be left on the activate area out of the grooves 40a, 40b. However, when patterning the aforementioned resist film, misalignment may occur. Thus, when the resist film is patterned to leave the resist film only within the grooves 40a, 40b, the misalignment occurs, so that a gap may be generated between the gate electrode 17 and the side of the grooves 40a, 40b. Because there would be a problem if such a condition occurs, when the resist film is patterned, the polysilicon is left on the activate area also out of the grooves 40a, 40b considering the misalignment. Consequently, it is possible to avoid a deficiency that the gap occurs between the polysilicon film 14 and the side of the grooves 40a, 40b.

Next, silicon oxide film (second insulation film) 41 is formed on the device formation side of the semiconductor 10 as shown in FIG. 15. The silicon oxide film 41 can be formed according to, for example, high density plasma CVD method and the film thickness is, for example, about 600 nm. The grooves 40a, 40b are fully filled with this silicon oxide film 41. That is, a part of the grooves 40a, 40b is already filled with the polysilicon film 14 while the remaining part is filled with this silicon oxide film 41.

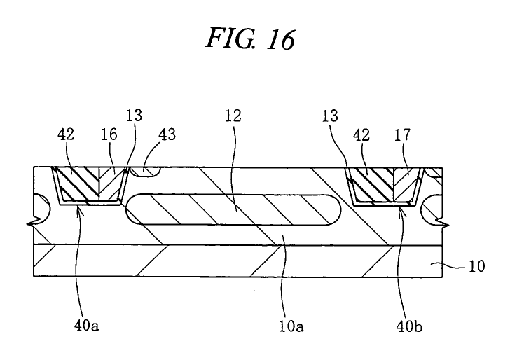

Subsequently, by removing unnecessary silicon oxide film 41 and polysilicon film 14 using the CMP method, a isolation area 42 is formed as shown in FIG. 16. That is, with the silicon oxide film 41 and the polysilicon film 14 formed within the grooves 40a, 40b being left therein, the other unnecessary silicon oxide film 41 and polysilicon film 14 are removed.

In this way, the isolation area 42 and the gate electrodes 16, 17, buried in the grooves 40a, 40b, can be formed.

Next, the p-type well 10a is formed according to photo lithography technology and ion implantation method. The p-type well 10a can be formed by implanting boron or boron fluoride, which is p-type impurity according to ion implantation method.

Subsequently, the charge accumulating area 12 is formed within the p-type well 10a according to photo lithography technology and ion implantation method. This charge accumulating area 12 can be formed by implanting for example, phosphorous, which is n-type impurity, at a dose amount of 2.0×10¹³/cm² with an energy of 200 keV. Because the charge accumulating area 12 can be formed by implanting phosphorous with a relatively high energy, it is not in contact with the device formation side (surface) of the semiconductor substrate 10.

Next, the resist film is patterned so that a part of the activate area adjacent to the side where the gate electrodes 16, 17 of the grooves 40a, 40b are formed is open according to photo lithography technology. Then, high density n-type impurity diffusion area 43 is formed by ion implantation with the patterned resist film as a mask. The high density n-type impurity diffusion area 43 is formed by implanting for example, arsenic, which is n-type impurity, at a dose amount of 1.0×10¹⁵/cm² with an energy of 40 keV. By implanting arsenic, which is heavier than phosphorus with a relatively low energy, the high density n-type impurity diffusion area 43 can be formed only in the vicinity of the semiconductor substrate 10. Consequently, the charge accumulating area 12 is formed at a deep portion in the p-type well 10a and the high density n-type impurity diffusion area 43 is formed at a shallow portion in the p-type well 10a. Therefore, the high density n-type impurity diffusion area 43 can be formed above and apart from the charge accumulating area 12, so that the vertical type MIS transistor Tr2 can be formed with the charge accumulating area 12 as a source area and the high density n-type impurity diffusion area 43 as a drain area.

After that, the wire 32 can be formed in the same process as described about the first embodiment. That is, after the interlayer insulating film 24 is formed, the connecting hole 25 is formed in this interlayer insulating film 24. Then, by filling this connecting hole 25 with titan/titan nitride film 26 and tungsten film 27, the plug 28 is formed. After that, the titan/titan nitride film 29, the aluminum film 30 and titan/titan nitride film 31 are formed on the plug 28 and the interlayer insulating film 24 successively, these films are patterned to form the wire 32.

In this way, the image sensor of the second embodiment can be formed.

### Third Embodiment

Although a case where both the gate electrode 16 and the isolation area 42 are formed within the groove 40a has been described about the second embodiment, the third embodiment will be described about a case where the gate electrode 16 is formed within the groove 40a with reference to the accompanying drawing.

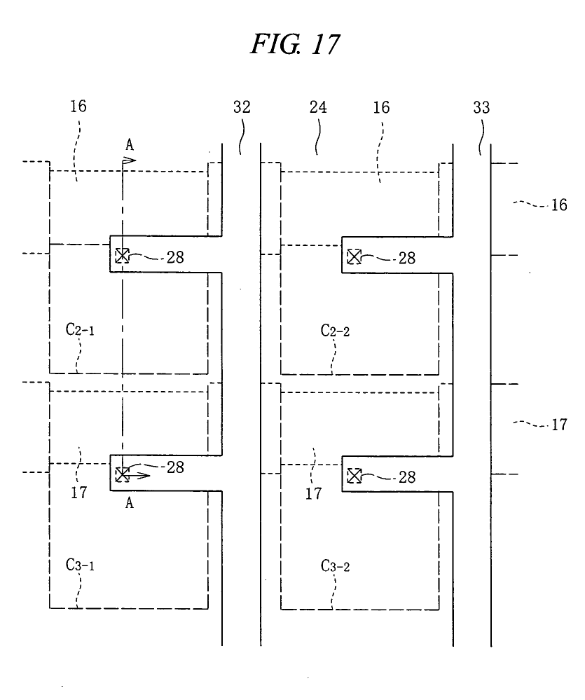

FIG. 17 is a plan view of a part of the light receiving portion of the image sensor of the third embodiment as seen from above. In this FIG. 17 also, the wires 32, 33 are formed in parallel to each other on the interlayer insulating film 24 like the second embodiment and the wires 32, 33 are provided with extracted lines. The wire 32 is just the scanning line 2a or connected electrically to the scanning line 2a. Likewise, the wire 33 is just the scanning line or connected electrically to the scanning line 2b.

Then, the wires 32, 33 are connected electrically to the plugs 28 at an end of each extracted line. The plug 28 goes through the interlayer insulating film 24 and the two plugs 28 connected to the wire 32 are connected to the cells C₂₋₁, C₃₋₁. The two plugs 28 connected to the wire 33 are connected to the cells C₂₋₂, C₃₋₂.

The gate electrode 16 is formed in these cells C₂₋₁, C₂₋₂ formed under the interlayer insulating film 24 and the gate electrode 17 is formed in the cells C₃₋₁, C₃₋₂. The gate electrodes 16, 17 intersect the wires 32, 33 at right angle and the gate electrodes 16, 17 are connected electrically to the scanning lines 1b, 1c as shown in FIG. 1.

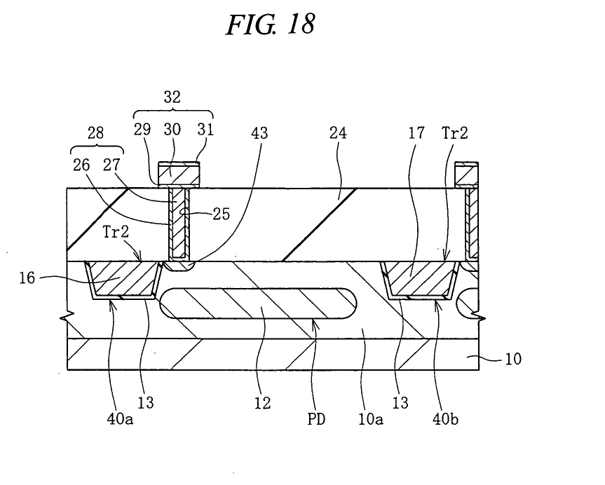

Next, FIG. 18 shows a sectional view taken along the line A-A in FIG. 17. Referring to FIG. 18, grooves 40a, 40b are formed in the semiconductor substrate 10 with a predetermined interval and the p-type well 10a is formed within the activate area between the grooves 40a and the groove 40b. The p-type impurity such as boron, boron fluoride is implanted into this p-type well 10a.

The charge accumulating area 12 is formed in the p-type well 10a. A part of the pn junction type photo diode PD is formed in the charge accumulating area 12 and the photo diode PD accumulates electric charges generated by converting impinging light photo-electrically. The charge accumulating area 12 is formed by implanting for example, phosphorous which is n-type impurity.

With such a structure, pn junction is produced on the boundary between the p-type well 10a implanted with the p-type impurity and the charge accumulating area 12 and the photo diode PD is formed with this p-type well 10a and the charge accumulating area 12.

The gate insulating film 13 is then formed on the sides and bottom of the grooves 40a, 40b and the gate electrodes 16, 17 are formed within the grooves 40a, 40b via this gate insulating film 13. Although according to the second embodiment, the gate electrode 16 and the isolation area 42 are formed within the groove 40a, according to the third embodiment, only the gate electrode 16 is formed.

The high density n-type impurity diffusion area 43 is formed in the activate area adjacent to the groove 40a.

In case of the third embodiment, the charge transferring MIS transistor Tr2 is constructed in a vertical structure like the second embodiment. That is, the charge transferring MIS transistor Tr2 of the third embodiment is comprised of the charge accumulating area 12 (source area), the high density n-type impurity diffusion area 43 (drain area), the gate electrode 16 formed within the groove 40a, and the gate insulating film 13.

Next, the interlayer insulating film 24 is formed on the semiconductor substrate 10 and the connecting hole 25 is formed in this interlayer insulating film 24. This connecting hole 25 is filled with titan/titan nitride film 26 and tungsten film 27 so as to form the plug 28. The wire 32 comprised of laminated film to successively have titan/titan nitride film 29, the aluminum film 30 and titan/titan nitride film 31 is formed on this plug 28.

In the cell C₂₋₁ of the third embodiment, the charge accumulating area 12 cannot be approached to the groove 40b. The reason is that otherwise, an unnecessary transistor is formed. That is, such an unnecessary MIS transistor can be formed with the charge accumulating area 12 in the cell C₂₋₁, the charge accumulating area in the cell C₃₋₁ seen partly on the right side of FIG. 18, the gate insulating film 13 and gate electrode 17 formed in the groove 40b.

The cell Cᵣ₋ₛ of the image sensor of the third embodiment is constructed with the above structure and its structure is different only in that the gate electrode 16 is buried in the groove 40a. Therefore, the third embodiment exerts the same effect as described in the second embodiment.

That is, because the charge accumulating area 12 is formed deep in the p-type well 10a and the charge accumulating area 12 itself can be used as a source area of the charge transferring MIS transistor Tr2, the leakage current can be reduced without an influence of the surface.

By disposing the charge transferring MIS transistor Tr2 and the photo diode PD in a vertical direction, the cell size can be reduced while maintaining the light receiving area.

Further, because the cell size can be reduced, the quantity of the image sensors which can be formed on the wafer can be increased. Therefore, the price of each image sensor can be reduced and the production cost can be reduced.

Next, the manufacturing method of the image sensor according to the third embodiment will be described with reference to the accompanying drawings.

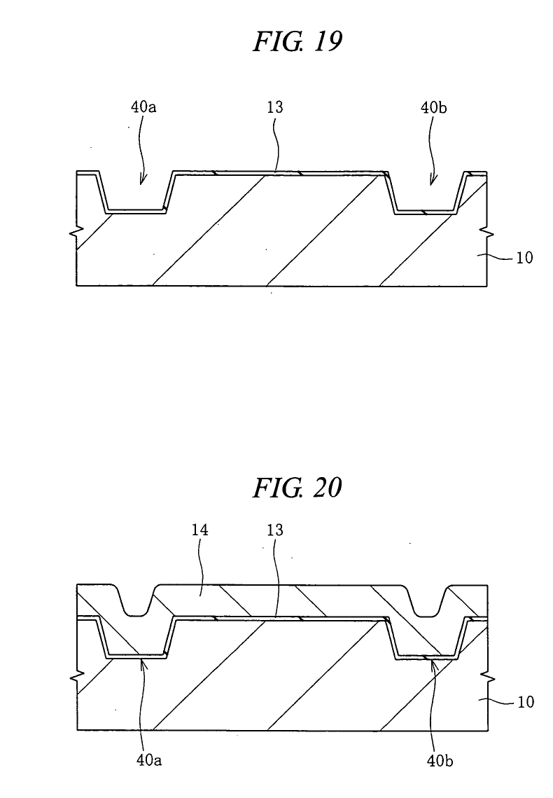

As described about the second embodiment, the semiconductor substrate 10 obtainable with the p-type impurity, for example boron or boron fluoride, being implanted into a mono-crystal silicon is prepared. Then, the grooves 40a, 40b are formed using photo lithography technology and etching technology as shown in FIG. 19. After that, the gate insulating film 13 is formed on the semiconductor substrate 10. This gate insulating film 13 is comprised of, for example, silicon oxide and can be formed according to, for example, thermal oxidation method. In the meantime, the gate insulating film 13 may be formed of high-k film.

Subsequently, the polysilicon film (first conductive film) 14 is formed on the semiconductor substrate 10 as shown in FIG. 20. The polysilicon film 14 can be formed using, for example, the CVD method.

Next, the resist film is applied onto the polysilicon film 14, and then the resist film is patterned by exposing to light and developing. Upon patterning, the resist film is left in the grooves 40a, 40b and on a part of the activate areas adjacent to the grooves 40a, 40b.

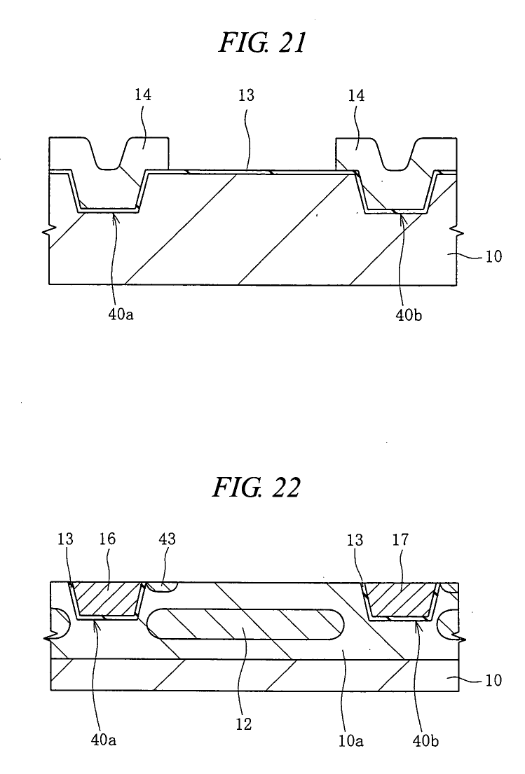

By etching with the patterned resist film as a mask, the polysilicon film 14 having a pattern as shown in FIG. 21 is formed. As shown in FIG. 21, the patterned polysilicon film 14 fills the grooves 40a, 40b and at the same time, is formed on the activate area adjacent to the grooves 40a, 40b out of the grooves 40a, 40b. The reason is that the misalignment is considered as described in the second embodiment.

Subsequently, the unnecessary polysilicon film 14 formed on the activate area is removed by polishing according to the CMP method. In this way, the gate insulating film 13 is formed on the sides and bottom of the grooves 40a, 40b as shown in FIG. 22 so that the gate electrodes 16, 17 can be formed on this gate insulating film 13.

Next, the p-type well 10a is formed in the active area of the semiconductor substrate 10 according to photo lithography technology and ion implantation method. The ion implantation for forming the p-type well 10a is executing by implanting p-type impurity such as boron, boron fluoride.

After the resist film is formed such that a part of the active area is open using photo lithography technology, the charge accumulating area 12 is formed within the p-type well 10a as shown in FIG. 22 by implanting ion with this resist film as a mask. This ion implantation is carried out by implanting, for example, phosphorous at a dose amount of about 2.0×10¹³/cm² with an energy of about 200 keV. By implanting phosphorus with a high energy, the charge accumulating area 12 can be formed such that it is not in contact with the surface of the semiconductor substrate 10.

Next, the resist film is formed such that a part of an area adjacent to the grooves 40a, 40b is open, and then the high density n-type impurity diffusion area 43 is formed as shown in FIG. 22 by implanting ions with this resist film as a mask. This ion implantation is carried out by implanting for example, arsenic at a dose amount of about 1.0×10¹⁵/cm² with an energy of about 40 keV.

After that, the wire 32 can be formed in the same process as in the method described about the second embodiment. That is, after the interlayer insulation film 24 is formed, the connecting hole 25 is formed in this interlayer insulating film 24. Then, this connecting hole 25 is filled with titan/titan nitride film 26 and tungsten film 27 so as to form the plug 28. After that, the titan/titan nitride 29, the aluminum 30 and the titan/titan nitride film 31 are formed on the plug 28 and the interlayer insulating film 24 successively and the wire 32 is formed by patterning these films.

In this way, the image sensor of the third embodiment can be manufactured.

According to the manufacturing method of the image sensor according to the third embodiment, the photo diode PD and the vertical type MIS transistor can be formed in a simpler process than the manufacturing method of the image sensor of the second embodiment. That is, because according to the third embodiment, only the gate electrode 16 is formed in the groove 40a although the second embodiment includes a process for forming the gate electrode 16 and the isolation area 42 in the groove 40a, the process can be simplified.

In the foregoing, the invention made by the inventors of the present invention has been concretely described based on the embodiment. However, it is needless to say that the present invention is not limited to the foregoing embodiment and various modifications and alterations can be made within the scope of the present invention.

Although the above-described embodiment adopts a structure in which the p-type well is formed within the semiconductor substrate by implanting the p-type impurity and the charge accumulating area is formed by implanting the n-type impurity into this p-type well, for example, it is permissible to form the p-type well in the semiconductor substrate by implanting the n-type impurity and then form the charge accumulating area by implanting the n-type impurity into this p-type well.

Although the p-type well is formed in the above-described embodiments, it is permissible to avoid the formation of this well.

The present invention exerts following effects.

That is, the cell area can be reduced while maintaining the light receiving area and the leakage current can be reduced.

What is claimed is:

1. A solid-state imaging device having a plurality of cells for converting incident light to electric charge on a semiconductor substrate thereof, the cell comprising:
(a) a charge accumulating area for accumulating the electric charge; and
(b) a field effect transistor for transferring the electric charge accumulated in the charge accumulating area out of the cell,
wherein the charge accumulating area is a semiconductor area formed by implanting impurity of first conductive type into the interior organization of the semiconductor substrate such that it extends substantially in parallel to the surface of the semiconductor substrate while a part thereof extends to the surface of the semiconductor substrate and is exposed, and
wherein, in the field effect transistor, a source area thereof being connected to the portion extended to the surface of the semiconductor substrate, of the charge accumulating area; a gate electrode is provided above an area of the charge accumulating area that is adjacent to the portion extending to the surface of the semiconductor substrate and that is exposed on the surface of the semiconductor substrate; and when the charge accumulating area is projected onto the device formation side of the semiconductor substrate, there existing an overlapping area between the charge accumulating area and the drain area of the field effect transistor.

2. The solid-state imaging device according to claim 1, wherein when the gate electrode and the charge accumulating area are projected onto the device formation side of the semiconductor substrate, both of them have an overlapping area.

3. A solid-state imaging device having a plurality of cells for converting incident light to electric charge on a semiconductor substrate thereof, comprising:
(a) a plurality of grooves formed on the semiconductor substrate; and
(b) the cells formed within the groove and on the active area,
wherein the cell has:
(c) a charge accumulating area for accumulating the electric charge; and
(d) a field effect transistor for transferring the electric charges accumulated in the charge accumulating area out of the cell,
wherein the charge accumulating area is a semiconductor area formed by implanting the impurity of the first conductive type into the interior organization of the active area, and
wherein the field effect transistor includes:
(d1) gate insulating film formed on the sides and bottom of the groove;
(d2) a gate electrode formed on the gate insulating film; and
(d3) a drain area formed above and apart from the charge accumulating area and in the active area.

4. The solid-state imaging device according to claim 3, wherein the groove is filled with both device separating film for separating the cell and the gate electrode.

5. The solid-state imaging device according to claim 3, wherein the groove is filled with the gate electrode.

6. The solid-state imaging device according to claim 3 wherein the charge accumulating area is not in contact with the groove.

7. The solid-state imaging device according to claim 3, wherein the charge accumulating area is to be a source area of the field effect transistor.

8. The solid-state imaging device according to claim 3, wherein the semiconductor substrate is formed by implanting impurity of a different conductive type from the first conductive type.

9. The solid-state imaging device according to claim 3, wherein a well is formed in the semiconductor substrate by implanting impurity of a different conductive type from the first conductive type, and
wherein the charge accumulating area is formed within the well.

10. A manufacturing method of solid-state semiconductor substrate having a plurality of cells for converting incident light to electric charge in the semiconductor substrate, comprising the steps of:
(a) forming a plurality of grooves in the semiconductor substrate;
(b) forming a first insulating film on the surface of the semiconductor substrate containing the groove;
(c) forming a first conductive film on the first insulating film formed such that the first conductive film fills the groove;
(d) leaving the first conductive film within the groove and on a part of the active area in contact with the groove by patterning the first conductive film;
(e) forming a gate electrode comprised of the first conductive film within the groove by polishing a surface of the semiconductor substrate in which the groove is formed according to a chemical mechanical polishing method;
(f) forming charge accumulating area in which the electric charge is accumulated by implanting the impurity of the first conductive type into the interior organization of the active area; and
(g) forming a drain area above and apart from the charge accumulating area by implanting the impurity of the first conductive type.

11. The manufacturing method of the solid-state imaging device according to claim 10 wherein
the step (d), after leaving the first conductive film in a part of the groove, forms a second insulating film within the groove and on the active area and
the step (e) forms the gate electrode comprised of the first conductive film and a isolation area comprised of the second insulating film within the groove.
